(19) United States
(12) Patent Application Publication
(10) Pub. No.: US 2018/0233538 A1
(43) Pub. Date: Aug. 16, 2018

(54) MEMORY DEVICE

(71) Applicant: TOSHIBA MEMORY CORPORATION, Tokyo (JP)

(72) Inventors: Tetsu Morooka, Yokkaichi (JP); Takeshi Takagi, Yokkaichi (JP); Takayuki Tsukamoto, Yokkaichi (JP)

(73) Assignee: TOSHIBA MEMORY CORPORATION, Tokyo, (JP)

(21) Appl. No.: 15/693,998

(22) Filed: Sep. 1, 2017

(30) Foreign Application Priority Data
Feb. 15, 2017 (JP) 2017-026042

(51) Int. Cl. H01L 27/24; H01L 45/00

(52) U.S. Cl. CPC H01L 27/249; H01L 45/1226; H01L 45/1246; G11C 13/0007; H01L 45/146; H01L 45/1253; H01L 45/08

(57) ABSTRACT

A memory device includes a first interconnection extending in a first direction; a second interconnection crossing the first interconnection and extending in a second direction; a resistance change film provided between the first interconnection and the second interconnection, and an intermediate film provided between the second interconnection and the resistance change film. The intermediate film is in contact with the second interconnection, and includes an insulating material.

### CROSS-REFERENCE TO RELATED APPLICATIONS

This application is based upon and claims the benefit of priority from Japanese Patent Application No. 2017-026042, filed on Feb. 15, 2017; the entire contents of which are incorporated herein by reference.

### FIELD

Embodiments relate generally to a memory device.

### BACKGROUND

There is a memory device including a plurality of memory cells such as resistance change type cells, and interconnections connected to the memory cells. In such a memory device, it is difficult to distinguish a leakage current between interconnections from a cell current flowing through a memory cell in a low resistance state. Thus, it cannot be determined whether good electrical insulation is provided between interconnections or not in some cases.

### BRIEF DESCRIPTION OF THE DRAWINGS

FIG. 1 is a schematic sectional view showing a memory device according to a first embodiment;

FIG. 2 is a schematic sectional view showing a memory cell of the memory device according to the first embodiment;

FIG. 3 is a schematic sectional view showing a memory device according to a first variation of the first embodiment;

FIG. 4 is a schematic sectional view showing a memory device according to a second variation of the first embodiment;

FIG. 5 is a schematic sectional view showing a memory device according to a second embodiment;

FIG. 6 is a schematic sectional view showing a memory device according to a first variation of the second embodiment;

FIG. 7 is a schematic sectional view showing a memory device according to a second variation of the second embodiment; and

FIG. 8 is a schematic sectional view showing a memory device according to a third embodiment.

### DETAILED DESCRIPTION

According to one embodiment, a memory device includes a first interconnection extending in a first direction; a second interconnection crossing the first interconnection and extending in a second direction; a resistance change film provided between the first interconnection and the second interconnection; and an intermediate film provided between the second interconnection and the resistance change film. The intermediate film is in contact with the second interconnection, and includes an insulating material.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

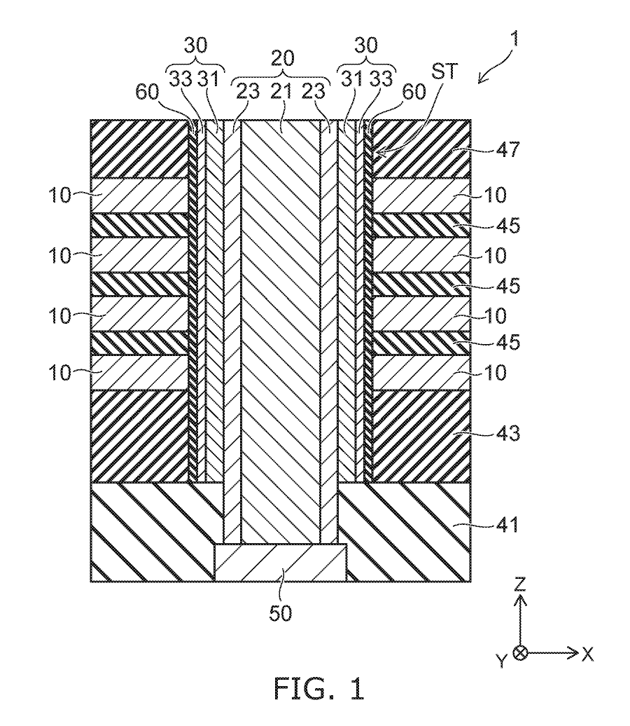

FIG. 1 is a schematic sectional view showing a memory device 1 according to a first embodiment. The memory device 1 is a non-volatile resistance change type memory device, and includes a word line 10, a bit line 20, and a resistance change film 30. The word line 10 extends, for example, in the Y-direction and crosses the bit line 20 extending in the Z-direction. The resistance change film 30 is provided between the word line 10 and the bit line 20 in a portion where the word line 10 crosses the bit line 20.

As shown in FIG. 1, a plurality of word lines 10 is stacked on an insulating film 41 and an insulating film 43. The insulating films 41 and 43 are stacked on a substrate (not shown), for example, a silicon substrate. The insulating film 41 is, for example, a silicon nitride film, and the insulating film 43 is, for example, a silicon oxide film.

The word lines 10 are stacked, for example, in the Z-direction with an insulating film 45 interposed. The word line 10 contains, for example, titanium nitride (TiN), and the insulating film 45 is, for example, a silicon oxide film. An insulating film 47 is provided on the uppermost word line 10. The insulating film 47 is, for example, a silicon oxide film.

The bit line 20 extends in the Z-direction along the end surfaces of the word line 10, the insulating films 43, 45, and 47. The bit line 20 is provided in a slit ST which divides, for example, the word line 10 and the insulating films 43, 45, and 47. The bit line 20 includes, for example, a conductive core 21 and a metal film 23. The metal film 23 covers, for example, the side surface of the conductive core 21 and extends in the Z-direction. The conductive core 21 contains, for example, silicon. The metal film 23 contains, for example, TiN. Further, the memory device 1 includes, for example, a plurality of bit lines 20 disposed along the slit ST extending in the Y-direction.

The bit line 20 further extends through the insulating film 41 and is connected to a global bit line 50. The global bit line 50 is electrically connected, for example, to a peripheral circuit (not shown). The global bit line 50 contains, for example, TiN.

The resistance change film 30 has a structure in which a low-resistance layer 31 and a barrier layer 33 are stacked. Here, the “low-resistance layer” refers to a layer having a lower resistance than the barrier layer. The low-resistance layer 31 contains, for example, titanium oxide (TiO₂) or tungsten oxide (WO₃). The barrier layer 33 contains, for example, amorphous silicon (α-Si). Further, the barrier layer 33 may contain at least one of silicon, silicon oxide, aluminum oxide, and hafnium oxide.

The memory device 1 further includes an intermediate film 60 provided between the word line 10 and the resistance change film 30. The intermediate film 60 contains an insulating material and is in contact with the word line 10. The intermediate film 60 contains, for example, a material different from the resistance change film 30. The intermediate film 60 is, for example, a silicon oxide film. Further, the intermediate film 60 contains at least one of silicon oxide, silicon nitride, aluminum oxide, hafnium oxide, tantalum oxide, niobium oxide, and titanium oxide.

The intermediate film 60 and the resistance change film 30 are stacked on the wall surface of the slit ST using, for example, ALD (Atomic Layer Deposition). In an initial state after the intermediate film 60 is formed on the wall surface of the slit ST and until a voltage is applied between the word line 10 and the bit line 20, the intermediate film 60 electrically insulates the word line 10 from the bit line 20. In contrast, the resistance change film 30 is in a low-resistance state in the initial state, and reversibly transits from the low-resistance state to a high-resistance state by a predetermined voltage applied between the word line 10 and the bit line 20.

For example, when a reset voltage is applied between the word line 10 and the bit line 20, the intermediate film 60 is brought into a conductive state, and the word line 10 is electrically and irreversibly connected to the resistance change film 30. Thereafter, the resistance change film 30 transits from the low-resistance state to a high-resistance state. Note that, the description is given in the specification by referring to the transition of the resistance change film 30 from a high-resistance state to a low-resistance state as “set”, and the reverse thereof as “reset”.

For example, in the case where the reset voltage is applied to the resistance change film 30 in a low-resistance state and the intermediate film 60 which is in the insulating condition under the initial state, electrical breakdown occurs due to an electric field induced in the intermediate film 60. Thereby, a current pathway is formed in the intermediate film 60, and electrically connects the word line 10 and the resistance change film 30. Thereafter, the resistance change film 30 transits from the low-resistance state to a high-resistance state by the reset voltage applied between the word line 10 and the bit line 20.

In the memory device 1, electrical insulation is provided between the word lines 10, between the bit lines 20, and between the word line 10 and the bit line 20 in an initial state by providing the intermediate film 60 between the word line 10 and the resistance change film 30. Thus, it becomes possible to test the electrical insulation between respective interconnections under applying a voltage where electrical breakdown is not induced in the intermediate film 60. Then, the current pathway is formed in the intermediate film 60, for example, by applying the reset voltage between the word line 10 and the bit line 20. Thereby, the word line 10 and the resistance change film 30 are electrically connected to each other, and it becomes possible to make a memory cell MC operate by applying a predetermined voltage between the word line 10 and the bit line 20. In this manner, it becomes possible in the memory cell MC including the resistance change film 30, which is in a low-resistance state in an initial state, to properly test the electrical insulation between interconnections connected thereto.

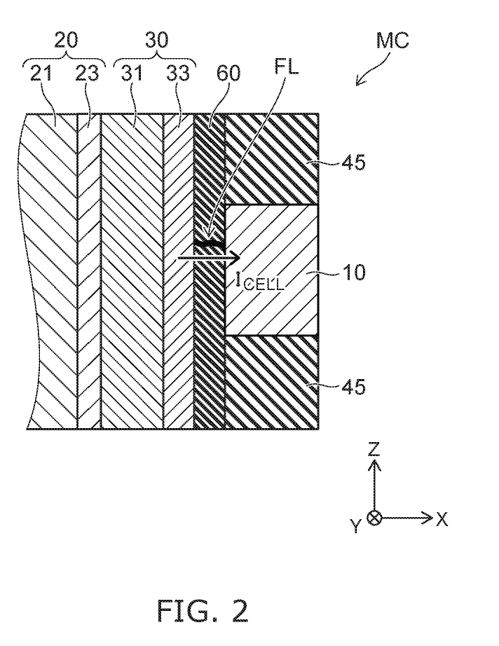

FIG. 2 is a schematic sectional view showing a memory cell MC of the memory device 1 according to the first embodiment. The memory cell MC is provided in a portion where the word line 10 crosses the bit line 20, and includes, for example, a part of the resistance change film 30. A plurality of memory cells MC are arranged in the Z-direction along the bit line 20. Further, memory cells MC are provided on both sides of the bit line 20 respectively at a portion where word lines 10 cross the bit line 20 on both side surfaces thereof (see FIG. 1).

The resistance change film 30 has a structure in which the low-resistance layer 31 and the barrier layer 33 are stacked. The low-resistance layer 31 contains, for example, a metal oxide such as TiO₂. The barrier layer 33 has a higher resistance than the low-resistance layer 31. For example, when the resistance change film 30 is in a low-resistance state, an electron in the low-resistance layer 31 tunnels toward the word line 10 through the barrier layer 33. Thus, the resistance value between the word line 10 and the bit line 20 is decreased. That is, the barrier layer 33 is provided with a thickness enabling an electron to tunnel toward the word line 10 from the low-resistance layer 31. Further, the resistance change film 30 is in a low-resistance state in an initial state after the resistance change film 30 is formed, and before a voltage is applied between the word line 10 and the bit line 20.

For example, when the potential of the bit line 20 is higher than the potential of the word line 10, a negative oxygen ion in the low-resistance layer 31 is attracted toward the bit line 20. Thereby, an electronic state changes in the vicinity of an interface between the low-resistance layer 31 and the barrier layer 33, and the tunneling of an electron through the barrier layer 33 is suppressed. As a result, the resistance change film 30 transits to a high-resistance state.

In contrast, when the potential of the word line 10 is higher than the potential of the bit line 20, a negative oxygen ion in the low-resistance layer 31 moves toward the barrier layer 33. Accordingly, the electronic state in the vicinity of the interface between the low-resistance layer 31 and the barrier layer 33 returns to the original state, and the electron can tunnel through the barrier layer 33. Therefore, the resistance change film 30 transits from the high-resistance state to the low-resistance state.

For example, when the reset voltage is applied to the resistance change film 30 and the intermediate film 60 in the initial state via the word line 10 and the bit line 20, a high electric field is induced in the intermediate film 60, and electrical breakdown occurs in the intermediate film 60.

Thereby, a filament FL which acts as a current pathway is formed in the intermediate film 60. Then, electrical connection through the filament FL is provided between the word line 10 and the resistance change film 30, and it becomes possible to make a cell current I_{CELL} flow therethrough. That is, the intermediate film 60 has a thickness such that the filament FL is formed by applying the reset voltage of several volts.

For example, in the case where the intermediate film 60 is a silicon oxide film or a silicon nitride film, the thickness thereof is several nanometers. The filament FL may be, for example, a current pathway through which an electron is transported via dangling bonds of silicon atoms, or may be a current pathway through which an electron is transported by metal ions moving into the intermediate film 60 from the word line 10 or the resistance change film 30, or may be both manners.

In the memory device 1, after testing the electrical insulation between interconnections under a lower voltage than the reset voltage of the memory cell MC, the irreversible conductance is made between the word line 10 and the resistance change film 30 by applying the reset voltage to the memory cell MC. Thus, it becomes possible to make the memory cell MC normally operate.

In the case where the intermediate film 60 is not provided, it is difficult to distinguish a leakage current between interconnections from the cell current I_{CELL}, and it cannot be determined whether the electrical insulation between interconnections is achieved or not. In the embodiment, it becomes possible to properly test the electrical insulation between interconnections by providing the intermediate film 60 between the word line 10 and the resistance change film 30.

It should be noted that the above-mentioned resistance change film 30 and intermediate film 60 are illustrated by an example, and the embodiment is not limited thereto. For example, the structure of the resistance change film 30 and the resistance changing mechanism thereof may be different from the above-mentioned examples, and a current pathway formed in the intermediate film 60 is not limited to the above-mentioned filament FL, and may be one which provides irreversible conductance between the word line 10 and the resistance change film 30.

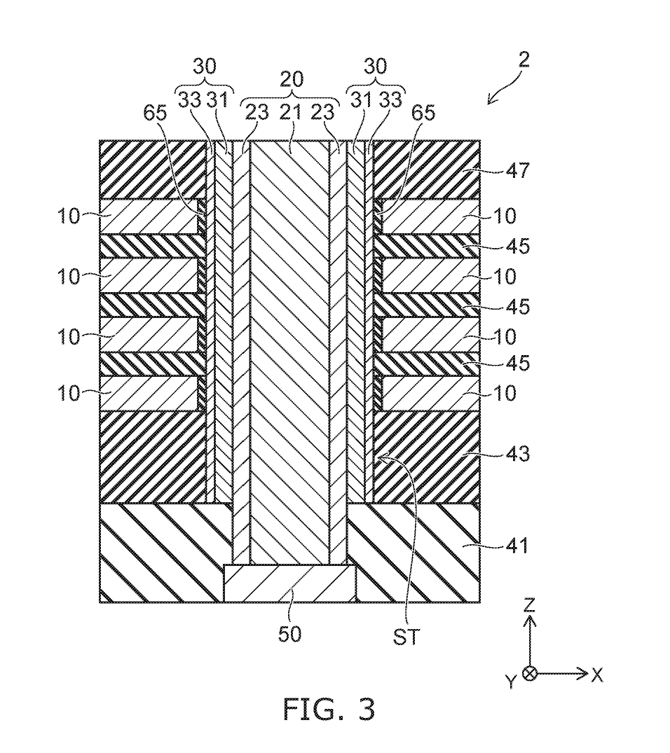

FIG. 3 is a schematic sectional view showing a memory device 2 according to a first variation of the first embodiment. The memory device 2 includes word lines 10, a bit line 20, and a resistance change film 30. The memory device 2 further includes intermediate films 65, and the intermediate films 65 are provided respectively between each word line 10 and the resistance change film 30.

As shown in FIG. 3, the intermediate films 65 are provided on the end surfaces of the word lines 10 respectively, and are arranged at positions separated from each other in the Z-direction. The intermediate films 65 are, for example, selectively formed on the end surfaces of the word lines 10 exposed on the wall surface of the slit ST. The intermediate films 65 in an initial state insulate the word lines 10 from the resistance change film 30, and, for example, have a thickness such that current pathways for providing electrical connection between the word lines 10 and the resistance change film 30 are formed when the reset voltage is applied between the word lines 10 and the bit line 20.

The intermediate films 65 are selectively formed on the end surfaces of the word lines 10 exposed on the wall surface of the slit ST. For example, the word lines 10 exposed on the wall surface of the slit ST is selectively etched to set back the end surface thereof, and thereafter, an insulating film that is to be the intermediate films 65 is formed on the inner surface of the slit ST. Subsequently, for example, the insulating film is removed using anisotropic RIE (Reactive Ion Etching) while leaving portions formed on the end surfaces of the word lines 10. Alternatively, metal oxide films that are to be the intermediate films 65 may be formed by oxidizing the end surfaces of the word lines 10. Insulating films that are to be the intermediate films 65 may be selectively deposited on the end surfaces of the word lines 10. The intermediate films 65 contain, for example, one of silicon oxide, silicon nitride, aluminum oxide, hafnium oxide, tantalum oxide, niobium oxide, and titanium oxide.

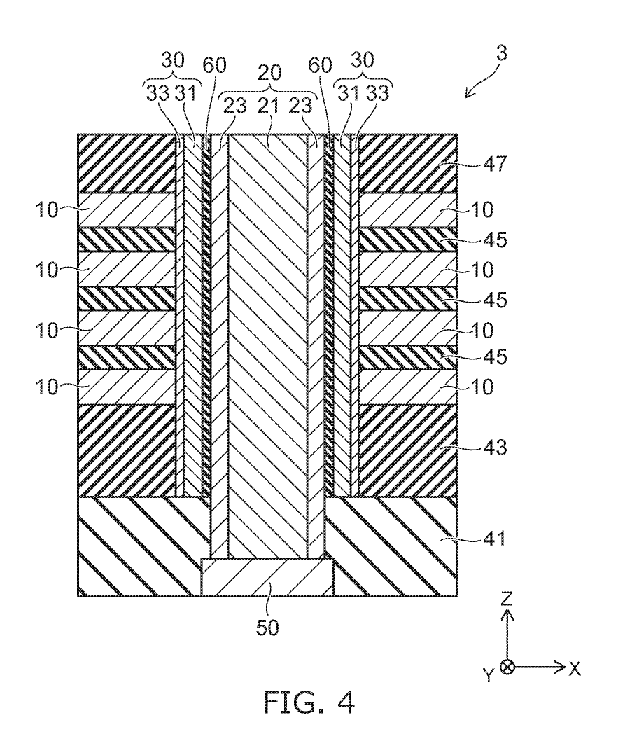

FIG. 4 is a schematic sectional view showing a memory device 3 according to a second variation of the first embodiment. In the memory device 3, an intermediate film 60 is provided between a bit line 20 and a resistance change film 30. The intermediate film 60 is provided in contact with the bit line 20. Further, the intermediate film 60 extends in the Z-direction along the bit line 20, and provides electrical insulation between the bit line 20 and the resistance change film 30 in an initial state. Thereby, when the resistance change film 30 has a low resistance in an initial state, the electrical insulation test can be performs between the bit lines 20, and between the word lines 10 and the bit line 20.

When the reset voltage is applied between one of the word lines 10 stacked in the Z-direction and the bit line 20, electrical breakdown occurs in the intermediate film 60. Thereby, a current pathway is formed in the intermediate film 60, and provides electrical connection between the bit line 20 and the resistance change film 30. Thus, it becomes possible to make the memory cells MC normally operate. Also in this example, the memory cells MC are provided in portions where the word lines 10 cross the bit line 20, and each include a part of the resistance change film 30.

When the resistance change film 30 is in a low-resistance state at an initial state, the electrical insulation test between the word lines 10 cannot be performed in this example, but the electrical isolation between the bit line 20 and the word lines 20 can be tested. Further, a current pathway for making the electrical connection between the bit line 20 and the resistance change film 30 can be formed by applying the reset voltage between at least one of the word lines 10 and the bit line 20. That is, it is necessary in the memory devices 1 and 2 to apply the reset voltage between each of the word lines 10 stacked in the Z-direction and the bit line 20 for making the current pathways between the word lines 10 and the resistance change film 30, and making the memory cells MC operate. In contrast, applying the reset voltage between at least one of the word lines 10 stacked in the Z-direction and the bit line 20 is required in the memory device 3.

### Second Embodiment

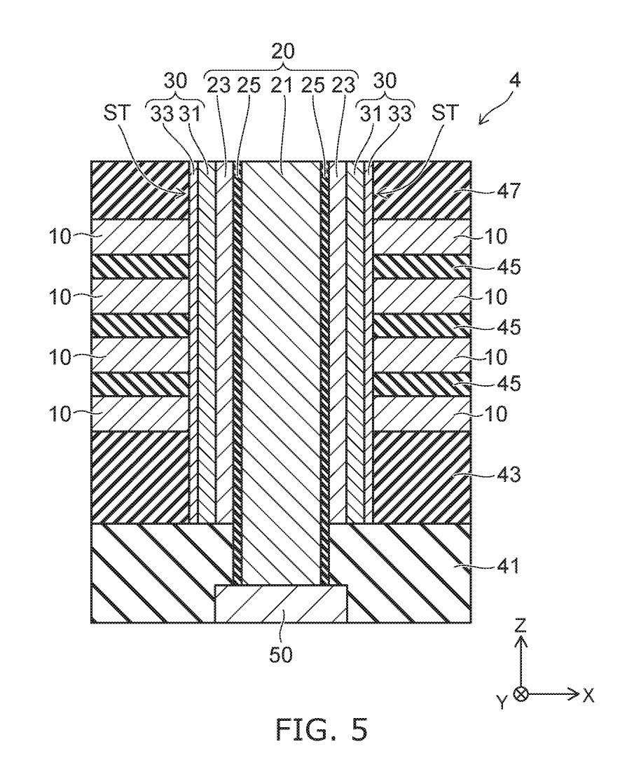

FIG. 5 is a schematic sectional view showing a memory device 4 according to a second embodiment. The memory device 2 includes a word line 10, a bit line 20, and a resistance change film 30. The resistance change film 30 includes a low-resistance layer 31 and a barrier layer 33 and has a low resistance in an initial state.

The word lines 10 are stacked in the Z-direction on an insulating film 43. An insulating film 45 is provided between the word lines 10 adjacent to each other in the Z-direction, and electrically insulates the word lines 10 from each other. The word lines 10 extend, for example, in the Y-direction.

The resistance change film 30 is provided on the inner wall of the slit ST. The slit ST extends, for example, in the Y-direction, and divides the word line 10 and the insulating films 43, 45, and 47. The bit line 20, which extends in the Z-direction, is formed in the slit ST after forming the resistance change film 30. Further, the memory device 4 includes a plurality of bit lines 20 arranged in the Y-direction along the slit ST. Memory cells MC are provided in portions where the word lines 10 cross the bit line 20, and each include a part of the resistance change film 30.

The bit line 20 shown in FIG. 5 includes a conductive core 21, a metal film 23, and an intermediate film 25. The intermediate film 25 is provided between the conductive core 21 and the metal film 23, and extends in the Z-direction along the conductive core 21. The intermediate film 25 is, for example, an insulating layer, and insulates the metal film 23 from the conductive core 21 in an initial state before applying a voltage between the word line 10 and the bit line 20. The intermediate film 25 contains, for example, one of silicon oxide, silicon nitride, aluminum oxide, hafnium oxide, tantalum oxide, niobium oxide, and titanium oxide.

As shown in FIG. 5, the conductive core 21 and the intermediate film 25 extends in an insulating film 41 and is electrically connected to a global bit line 50. The metal film 23 is provided between the intermediate film 25 and the resistance change film 30 in the slit ST.

In the memory device 4, when the resistance change film 30 is in a low-resistance state, it becomes possible to test the electrical insulations between the bit lines 20, and between the word lines 10 and the bit line 20 by providing the intermediate film 25. For example, when the reset voltage is applied between one of the word lines 10 and the conductive core 21, electrical breakdown occurs in the intermediate film 25, and a current pathway is formed between the conductive core 21 and the metal film 23. Thereby, it becomes possible to make the memory cells MC operate. Note that the current pathway formed in the intermediate film 25 is, for example, a filament FL as shown in FIG. 2.

Also in the memory device 4, the conductive core 21 and the metal film 23 can be electrically connected to each other by applying the reset voltage between at least one of the word lines 10 stacked in the Z-direction and the bit line 20.

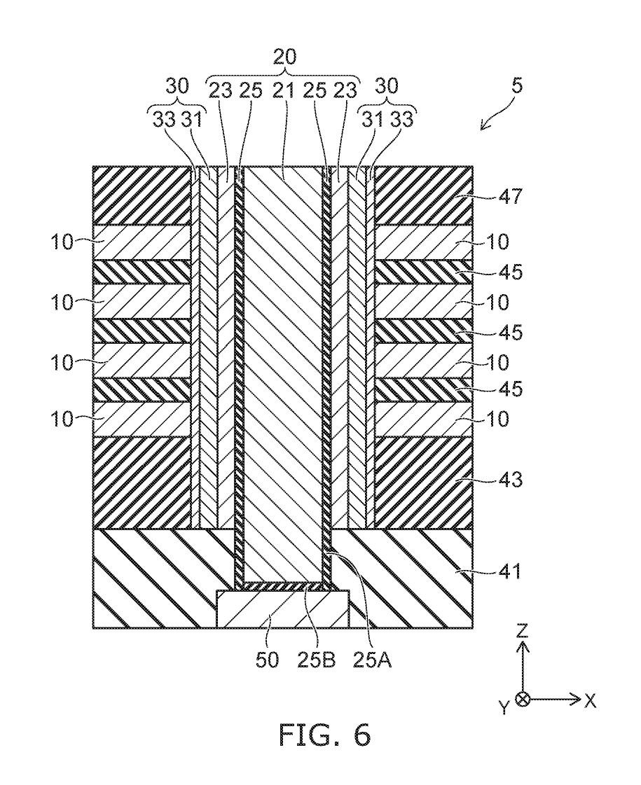

FIG. 6 is a schematic sectional view showing a memory device 5 according to a first variation of the second embodiment. Also in the memory device 5, a bit line 20 includes a conductive core 21, a metal film 23, and an intermediate film 25.

The intermediate film 25 shown in FIG. 6 contains a first portion 25A and a second portion 25B. The first portion 25A extends in the Z-direction along the conductive core 21. The second portion 25B is provided between the conductive core 21 and a global bit line 50.

The intermediate film 25 provides electrical insulation between the conductive core 21 and the global bit line 50 and between the conductive core 21 and the metal film 23 in an initial state. Thereby, for example, when the resistance change film 30 is in a low-resistance state, the electrical insulation between the global bit lines 50 can be tested.

Further, the intermediate film 25 has a thickness such that current pathways are formed between the conductive core 21 and the global bit line 50, and between the conductive core 21 and the metal film 23, when the reset voltage is applied between the word line 10 and the global bit line 50. That is, at least one current pathway is formed in each of the first portion 25A and the second portion 25B, and the current pathway is, for example, a filament FL shown in FIG. 2. Thereby, it is possible in the memory device 5 to make the memory cells MC operate after the electrical insulations are tested between the global bit lines 50.

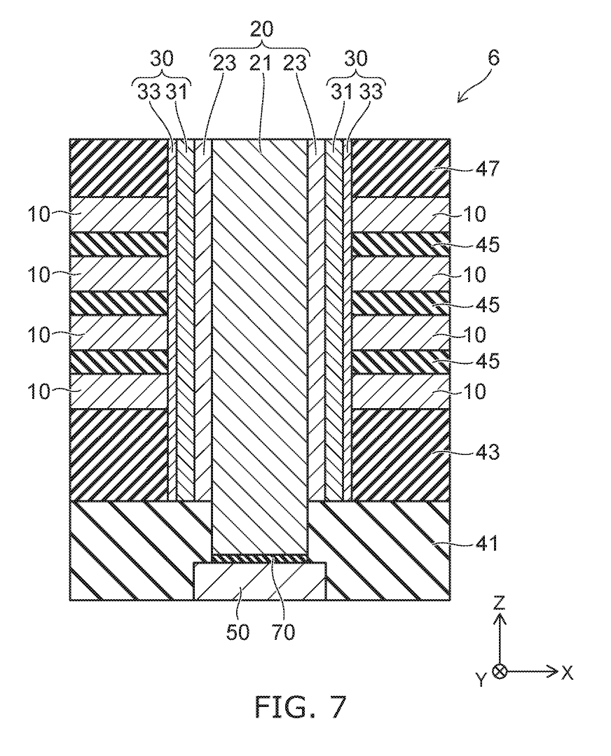

FIG. 7 is a schematic sectional view showing a memory device 6 according to a second variation of the second embodiment. The memory device 6 includes a word line 10, a bit line 20, and a resistance change film 30. The memory device 6 includes an intermediate film 70 provided between the bit line 20 and a global bit line 50.

As shown in FIG. 7, the bit line 20 includes a conductive core 21 and a metal film 23. The conductive core 21 extends in an insulating film 41. The intermediate film 70 is provided between a bottom end of the conductive core 21 and the global bit line 50. The intermediate film 70 provides electrical insulation between the conductive core 21 and the global bit line 50 in an initial state. Thereby, when the resistance change film 30, for example, is in a low-resistance state, the electrical insulations can be tested between the bit line 20 and the global bit line 50, and between the global bit lines 50.

The intermediate film 70 contains, for example, one of silicon oxide, silicon nitride, aluminum oxide, hafnium oxide, tantalum oxide, niobium oxide, and titanium oxide. Further, the intermediate film 70 has a thickness such that a current pathway is formed between the conductive core 21 and the global bit line 50 by applying, for example, the reset voltage between the word line 10 and the global bit line 50 when the resistance change film 30 is in a low-resistance state. The current pathway formed in the intermediate film 70 is, for example, a filament FL shown in FIG. 2. Thereby, it is possible in the memory device 6 to make the memory cell MC operate after the electrical insulations are tested between the bit line 20 and the global bit line 50, and between the global bit lines 50.

### Third Embodiment

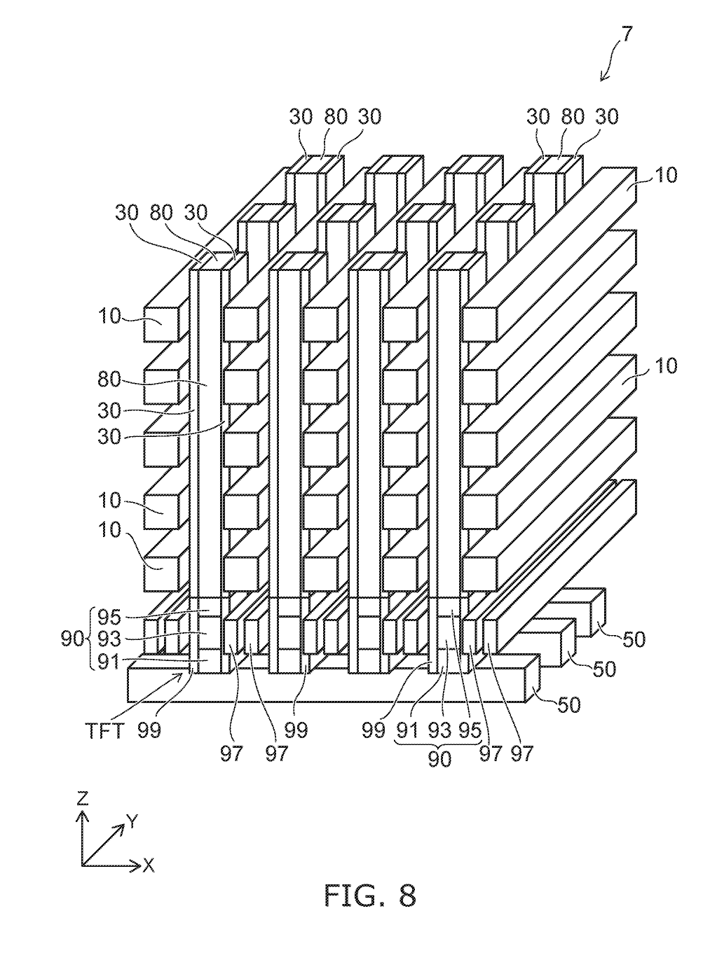

FIG. 8 is a schematic sectional view showing a memory device 7 according to a third embodiment. The memory device 7 is a non-volatile memory device including three-dimensionally disposed resistance change type memory cells MC. The memory device 7 includes word lines 10 extending in the Y-direction, local bit lines 80 crossing the word lines 10 and extending in the Z-direction, and resistance change films 30. A resistance change film 30 is provided between a word line 10 and a local bit line 80. Note that insulating films provided between respective interconnections are omitted in FIG. 8 for convenience in showing a structure of the memory device 7.

As shown in FIG. 8, the memory device 7 further includes a plurality of global bit lines 50 extending in the X-direction. The global bit lines 50 are arranged in the Y-direction. A plurality of local bit lines 80 is connected to each global bit line 50 through TFTs (Thin Film Transistors) respectively. The word lines 10 are stacked in the Z-direction along the local bit line 80 above the global bit lines 50. The resistance change film 30 extends, for example, in the Z-direction along the local bit line 80, and is positioned between the word lines 10 stacked in the Z-direction and the local bit line 80.

The TFTs each include a semiconductor layer 90, a gate electrode 97, and a gate insulating film 99. The semiconductor layer 90 extends in the Z-direction, and includes a drain region 91, a channel region 93, and a source region 95. The gate electrode 97 is provided on both sides of the semiconductor layer 90 in the X-direction, and faces the channel region 93 via the gate insulating film 99. Further, the gate electrode 97 extends in the Y-direction and is shared by a plurality of TFTs.

The memory cells MC of the memory device 7 are provided in portions where the word lines 10 cross the local bit line 80, and each includes a part of the resistance change film 30. Memory cells MC is provided on both sides of the local bit line 80 in the X-direction. Further, the word line 10 positioned between the local bit lines 80 adjacent to each other in the X-direction is shared by memory cells MC positioned on both sides thereof in the X-direction.

Further, the memory device 7 includes an intermediate film 60 (not shown, see FIG. 1) between word lines 10 and a resistance change film 30, for example. The intermediate film 60 insulates the word lines 10 from the resistance change film 30 in an initial state before applying a voltage between the word lines 10 and the local bit line 80. When the resistance change film 30 has a low resistance in an initial state, the electrical insulations can be tested between respective interconnections. Further, when the reset voltage for making the resistance change film 30 transit to a high-resistance state is applied between the word lines 10 and the local bit line 80, the current pathways making electrical connections between the word lines 10 and the resistance change film 30 are formed in the intermediate film 60, and it becomes possible to make the memory cells MC operate.

Further, the memory device 7 may include the intermediate film 60 between the local bit line 80 and the resistance change film 30 (see FIG. 4). Moreover, in place of the intermediate film 60, the local bit line 80 including the intermediate film 25 (see FIG. 5) may be disposed, or the intermediate films 70 (see FIG. 7) may be disposed between the local bit lines 80 and the TFTs respectively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A memory device comprising:
a first interconnection extending in a first direction;
a second interconnection crossing the first interconnection and extending in a second direction;
a resistance change film provided between the first interconnection and the second interconnection; and
an intermediate film provided between the second interconnection and the resistance change film, the intermediate film being in contact with the second interconnection and the resistance change film, and including an insulating material.

2. The device according to claim 1, wherein
the intermediate film is an insulating film including a current pathway electrically connecting the second interconnection and the resistance change film.

3. The device according to claim 2, wherein
the intermediate film includes silicon atoms, and
electrons are transported in the current pathway via dangling bonds of the silicon atoms.

4. The device according to claim 2, wherein
the intermediate film includes metal ions, and
electrons are transported in the current pathway by the metal ions.

5. The device according to claim 1, wherein the intermediate film contains a material different from the resistance change film.

6. The device according to claim 1, further comprising:
a plurality of second interconnections stacked in the first direction, the plurality of second interconnection including the second interconnection, and
interlayer insulating films provided between the plurality of second interconnections respectively, wherein
the intermediate film includes a material same as a material of the interlayer insulating film.

7. The device according to claim 1, further comprising:
a plurality of second interconnections stacked in the first direction, the plurality of second interconnection including the second interconnection, and
interlayer insulating films provided between the plurality of second interconnections respectively, wherein
the intermediate film includes parts separated from each other, the parts being provided between the respective second interconnections and the resistance change film.

8. The device according to claim 1, wherein
the resistance change film includes a first layer and a second layer, the second layer having a higher resistance than the first layer.

9. The device according to claim 3, wherein
the first layer contains titanium oxide or tungsten oxide, and
the second layer contains at least one of silicon, silicon oxide, aluminum oxide, and hafnium oxide.

10. The device according to claim 1, wherein
the first interconnection includes a conductive core extending in the first direction, and a metal film positioned between the conductive core and the resistance change film

11. The device according to claim 10, wherein the conductive core contains silicon.

12. A memory device comprising:
a first interconnection extends in a first direction;
a second interconnection extending in a second direction, and crossing the first interconnection;
a resistance change film provided between the first interconnection and the second interconnection; and
an intermediate film positioned between the resistance change film and the first interconnection, the intermediate film including an insulating material; and
a third interconnection electrically connected to a first end of the first interconnection, the first end being an end of the first interconnection in the first direction,
the first interconnection including a conductive core extending in the first direction and a metal film extending in the first direction, the metal film being positioned between the intermediate film and the conductive core.

13. The device according to claim 12, wherein
the intermediate film is an insulating film including a current pathway electrically connecting the resistance change film and the metal film.

14. A memory device comprising:
a first interconnection extending in a first direction, the first interconnection including a conductive core extending in the first direction and a metal film covering the conductive core, the metal film extending in the first direction along the conductive core;
a second interconnection extending in a second direction, and crossing the first interconnection;
a resistance change film provided between the metal film and the second interconnection;
a third interconnection electrically connected to the conductive core, the third interconnection being electrically connected to the resistance change layer via the conductive core and the metal film; and
an intermediate film provided between the conductive core and the third interconnection, the intermediate film including an insulating material.

15. (canceled)

16. The device according to claim 14, wherein
the intermediate film is an insulating film including a current pathway electrically connecting the conductive core and the third interconnection.

17. The device according to claim 14, wherein
the intermediate film includes a first portion positioned between the conductive core and the third interconnection, and a second portion extending in the first direction along the conductive core, and
the intermediate film is an insulating film that includes a first current pathway in the first portion and includes a second current pathway in the second portion between the conductive core and the metal film, the first pathway electrically connecting the conductive core and the third interconnection, and the second current pathway electrically connecting the conductive core and the metal film.
